(19) United States
(12) Patent Application Publication
(10) Pub. No.: US 2022/0385021 A1
(43) Pub. Date: Dec. 1, 2022

(54) LASER DEVICE

(71) Applicant: FURUKAWA ELECTRIC CO., LTD., Tokyo (JP)

(72) Inventors: Yuuki ISOBE, Tokyo (JP); Kazuaki KIYOTA, Tokyo (JP)

(73) Assignee: FURUKAWA ELECTRIC CO., LTD., Tokyo (JP)

(21) Appl. No.: 17/881,723

(22) Filed: Aug. 5, 2022

Related U.S. Application Data
(63) Continuation of application No. PCT/JP2021/005109, filed on Feb. 10, 2021.

(30) Foreign Application Priority Data
Feb. 12, 2020 (JP) 2020-021882

(51) Int. Cl. H01S 3/00; H01S 3/08

(52) U.S. Cl. CPC H01S 3/0071; H01S 3/08059; H01S 3/10053

(57) ABSTRACT

A laser device includes: a first reflecting unit; a second reflecting unit; a gain unit provided between the first reflecting unit and the second reflecting unit; a divider provided after the first reflecting unit and configured to divide laser light from the first reflecting unit into first light and second light; a first end portion positioned separately from the divider in a first direction, and positioned after the divider, the first end portion being configured to output, as output light, the first light or the first light that has been amplified; and a second end portion positioned separately from the divider in a second direction different from the first direction, the second end portion being configured to output the second light.

This application is a continuation of International Application No. PCT/JP2021/005109, filed on Feb. 10, 2021 which claims the benefit of priority of the prior Japanese Patent Application No. 2020-021882, filed on Feb. 12, 2020, the entire contents of which are incorporated herein by reference.

### BACKGROUND

The present disclosure relates to laser devices.

A known laser device includes a first reflecting unit, a second reflecting unit, and a gain unit between the first reflecting unit and the second reflecting unit, and outputs laser light from an output end (a front end) on an opposite side of the first reflecting unit, the opposite side being opposite to a side where the second reflecting unit and the gain unit are (for example, Japanese Laid-open Patent Publication No. 2019-140308).

In this type of laser device, rearward output light transmitted and output through an end portion (a rear end) is monitored by a measuring device, such as, a wavemeter or a power meter, for example, the end portion being on an opposite side of the second reflecting unit, the opposite side being opposite to a side where the output end is (Japanese Laid-open Patent Publication No. 2019-140308).

### SUMMARY

When reflectivity of the second reflecting unit is increased for increase in power of light output by this conventional laser device, power of the rearward output light is decreased and detection of characteristics including wavelength is made difficult.

There is a need for a laser device that facilitates detection of characteristics including wavelength of laser light.

According to one aspect of the present disclosure, there is provided a laser device including: a first reflecting unit; a second reflecting unit; a gain unit provided between the first reflecting unit and the second reflecting unit; a divider provided after the first reflecting unit and configured to divide laser light from the first reflecting unit into first light and second light; a first end portion positioned separately from the divider in a first direction, and positioned after the divider, the first end portion being configured to output, as output light, the first light or the first light that has been amplified; and a second end portion positioned separately from the divider in a second direction different from the first direction, the second end portion being configured to output the second light.

### BRIEF DESCRIPTION OF THE DRAWINGS

FIG. 1 is an exemplary and schematic plan view of a laser device according to an embodiment;

FIG. 2 is an exemplary and schematic plan view of a laser device according to a first modified example;

FIG. 3 is an exemplary and schematic plan view of a laser device according to a second modified example; and

FIG. 4 is an exemplary and schematic plan view of a laser device according to a third modified example.

### DETAILED DESCRIPTION

An exemplary embodiment of the present disclosure and modified examples thereof will be disclosed hereinafter. Configurations of the embodiment and modified examples described hereinafter and functions and results (effects) achieved by these configurations are just examples. The present disclosure may be implemented by configurations other than those disclosed hereinafter with respect to the embodiment and modified examples. Furthermore, the present disclosure achieves at least one of various effects (including derivative effects) achieved by these configurations.

The embodiment and modified examples described hereinafter include same components. Therefore, same functions and effects based on the same components of the embodiment and modified examples are achieved. Furthermore, same reference signs will hereinafter be assigned to these same components and any redundant explanation thereof may be omitted.

Ordinals are assigned for convenience to distinguish between parts and portions in this specification and do not indicate any priority or order.

In each drawing, an X direction is represented by an arrow X and a Y direction is represented by an arrow Y. The X direction and Y direction intersect each other and are orthogonal to each other. The X direction may be referred to as a longitudinal direction or lengthwise direction and the Y direction may be referred to as a transverse direction, width direction, or crosswise direction.

### EMBODIMENT

### Configuration of Laser Device

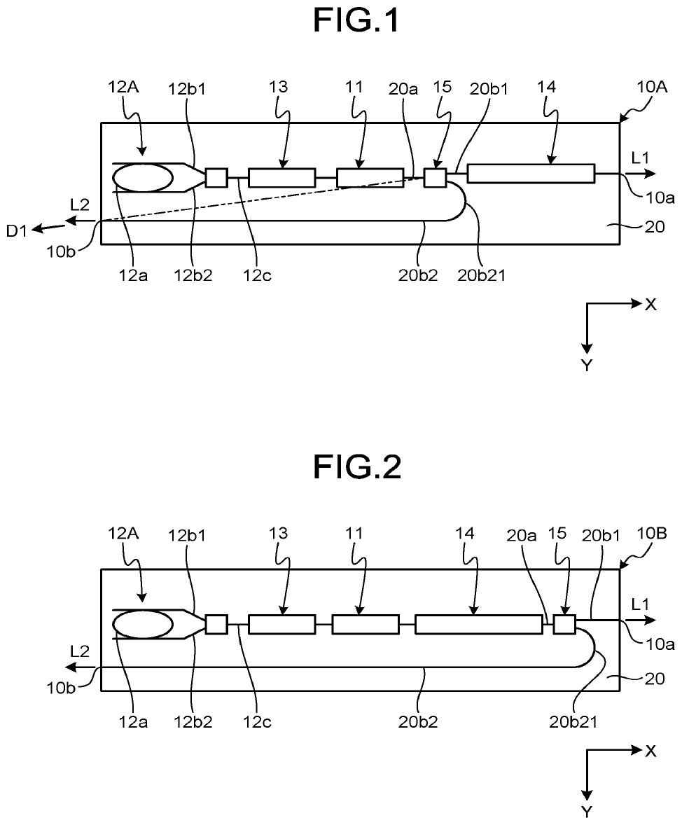

A configuration of a laser device 10A according to an embodiment will be described first. FIG. 1 is a plan view of the laser device 10A. As illustrated in FIG. 1, the laser device 10A includes a first DBR unit 11, a ring resonator filter 12A, a gain unit 13, an optical amplifier 14, and a divider 15. The laser device 10A is a semiconductor laser element and is a wavelength-tunable laser element. The laser device 10A is provided in a semiconductor layered substrate 20. The semiconductor layered substrate 20 is configured to have plural semiconductor layers layered over one another on a semiconductor substrate and to have predetermined functions of a waveguide, for example.

The first DBR unit 11, the ring resonator filter 12A, the gain unit 13, the optical amplifier 14, and the divider 15 are each made of an InP-based semiconductor material.

The first DBR unit 11 has a waveguide (not illustrated in the drawings) including a sampled grating-distributed Bragg reflector (SG-DBR) configuration. The first DBR unit 11 is an example of a first reflecting unit and also an example of a mirror.

The ring resonator filter 12A has: a ring waveguide 12a having a ring shape; and two optical coupler waveguides 12b1 and 12b2 that input and output laser light from and to the ring waveguide 12a. The optical coupler waveguides 12b1 and 12b2 opposite to each other with the ring waveguide 12a interposed between the optical coupler waveguides 12b1 and 12b2 are each optically coupled to the ring waveguide 12a. The optical coupler waveguides 12b1 and 12b2 each have: a linear arm portion branched from one waveguide 12c joined to the gain unit 13 at a position away toward the first DBR unit 11 from the ring waveguide 12a; and a connecting portion that inputs and outputs light from and to the ring waveguide 12a. The connecting portion, for example, is of a multimode interference waveguide type or is a directional coupler. A multimode interference waveguide type or a directional coupler may be used, for example, as the optical coupler waveguide 12b1 or 12b2. The ring resonator filter 12A configured as described above functions as a mirror having reflection characteristics that periodically change in relation to wavelength of light input from the waveguide 12c. The ring resonator filter 12A is an example of a second reflecting unit.

The gain unit 13 has a waveguide (not illustrated in the drawings) made of an active layer.

The optical amplifier 14 also has a waveguide (not illustrated in the drawings) made of an active layer.

In the above described configurations, the active layers have a multi Quantum well (MQW) structure made of, for example, a GaInAsP-based semiconductor material or an AlGaInAs-based semiconductor material. A passive waveguide is made of, for example, an i-type GaInAsP-based semiconductor material having a bandgap wavelength of 1300 nm. The waveguide having the SG-DBR configuration is made of, for example, a GaInAsP-based semiconductor material or an AlGaInAs-based semiconductor material and has portions with refractive indices different from each other, the portions being periodically arranged to form a diffraction grating.

A microheater (not illustrated in the drawings) is provided at each of the first DBR unit 11 and the ring resonator filter 12A. The microheaters are so-called resistance heating elements and generate heat according to supply of electric current. A wiring structure, such as an electrode or a conductor layer, for supply of electric current is provided in the microheaters.

The first DBR unit 11 and the ring resonator filter 12A form a laser resonator. The first DBR unit 11 has comb-like reflection peaks at periodic frequency intervals according to the inverse of the period of the diffraction grating. The first DBR unit 11 and the ring resonator filter 12A have periods different from each other and are configured to enable coarse adjustment of frequency of laser light by a method called the Vernier method. Heating the first DBR unit 11 with the microheater changes the refractive index of the first DBR unit 11 and thereby shifts the comb-like reflection peaks in the frequency axis direction. Similarly, heating the ring resonator filter 12A with the microheater changes the refractive index of the ring resonator filter 12A and shifts the comb-like reflection peaks in the frequency axis direction.

The gain unit 13 is positioned between the first DBR unit 11 and the ring resonator filter 12A. In other words, the ring resonator filter 12A is provided on an opposite side of the gain unit 13, the opposite side being opposite to a side where the first DBR unit 11 is provided. A pair of electrodes (not illustrated in the drawings) separated from each other is provided at the gain unit 13. Applying electric voltage to the pair of electrodes causes electric current to flow to the gain unit 13 and an optical amplification effect to be exerted. Laser oscillation thereby occurs.

The divider 15 is positioned on an opposite side of the first DBR unit 11, the opposite side being opposite to a side where the gain unit 13 and the ring resonator filter 12A are positioned. The divider 15 divides laser light propagated from the first DBR unit 11 through a waveguide 20a into first light heading to the optical amplifier 14 and second light different from the first light. The first light heads to the optical amplifier 14 via a waveguide 20b1 and the second light heads to an end portion 10b via a waveguide 20b2.

The optical amplifier 14 is positioned on an opposite side of the first DBR unit 11, the opposite side being opposite to a side where the gain unit 13 and the ring resonator filter 12A are positioned, and the optical amplifier 14 is positioned between the first DBR unit 11 and an end portion 10a that is an output end for laser light. The first light is input to the optical amplifier 14 via the waveguide 20b1 from the divider 15. Applying electric voltage to the optical amplifier 14 via an electrode (not illustrated in the drawings) causes electric current to flow to the optical amplifier 14 and an optical amplification effect to be exerted. The optical amplifier 14 optically amplifies laser light output from the first DBR unit 11 by laser oscillation, the first light from the divider 15 in this embodiment.

The laser device 10A outputs, from the end portion 10a, the laser light that has been amplified by the optical amplifier 14, that is, the first light that has been amplified by the optical amplifier 14. The laser light output from the end portion 10a is output light of the laser device 10A. The end portion 10a is an example of a first end portion and may also be referred to as an output end or a front end.

The waveguide 20b2 for the second light divided by the divider 15 has a curved portion 20b21. The curved portion 20b21 has a U-shape. Therefore, the direction in which the second light travels is changed by 180° at the curved portion 20b21.

An output ratio of the first light to light input to the divider 15 is preferably 80% or higher and 99% or lower, and more preferably 95% or higher.

The second light is output from the end portion 10b on an opposite end of the waveguide 20b2, the opposite end being opposite to an end where the divider 15 is. The end portion 10b is an example of a second end portion.

As illustrated in FIG. 1, the end portion 10a is positioned separately in the X direction from the divider 15. The end portion 10b is positioned separately in a D1 direction from the divider 15, the D1 direction being different from the X direction. Furthermore, the end portion 10a is positioned at an end of the X direction length of the laser device 10A (the semiconductor layered substrate 20) and the end portion 10b is positioned at an opposite end of the X direction length of the laser device 10A (the semiconductor layered substrate 20). The X direction is an example of a first direction and the D1 direction is an example of a second direction.

As described above, in this embodiment, the divider 15 divides the laser light from the first DBR unit 11 (first reflecting unit) into the first light and the second light. The end portion 10a (the first end portion) outputs, as output light of the laser device 10A, the first light that has been amplified by the optical amplifier 14. The end portion 10b (the second end portion) outputs the second light.

That is, the above described configuration enables the second light divided by the divider 15 to be used in testing. The configuration enables: use of more reliable output of laser light for testing as compared to a case where, for example, light that has been transmitted through a second reflecting unit without being reflected, that is, light that has leaked is used for testing like in the conventional configuration; and more reliable or more accurate examination results to be obtained.

Furthermore, in this embodiment, the end portion 10a is positioned separately in the X direction (the first direction) from the divider 15 and positioned on an opposite side of the divider 15, the opposite side being opposite to a side where the first DBR unit 11 is positioned. In addition, the end portion 10b is positioned separately in the D1 direction (the second direction) from the divider 15, the D1 direction being different from the X-direction.

Light that has not been optically coupled to the waveguides 20b1 and 20b2 at the divider 15 becomes stray light travelling in the semiconductor layer surrounding the waveguides in the semiconductor layered substrate 20 and this stray light tends to travel in the direction in which light is input from the first DBR unit 11 to the divider 15, that is, in the X direction. Therefore, if the end portion 10b were to be positioned separately in the X direction from the divider 15, the stray light would tend to be mixed into light output from the end portion 10b and might affect the detection accuracy. Usually, the light output from the end portion 10b is considerably weaker than the output light from the end portion 10a and will thus be more largely affected by the stray light. In contrast, in this embodiment, the end portion 10a is positioned on the opposite side of the divider 15, the opposite side being opposite to the side where the first DBR unit 11 is positioned, and the direction (the X direction or first direction) in which the end portion 10a is present in relation to the divider 15 and the direction (the D1 direction or second direction) in which the end portion 10b is present in relation to the divider 15 are different from each other. Therefore, mixing of the stray light into the second light (detected light) output from the end portion 10b is able to be reduced and the examination accuracy is thus able to be improved.

Furthermore, in this embodiment, the laser device 10A includes the waveguide 20b2 having the curved portion 20b21 and joining the divider 15 and the end portion 10b to each other. In addition, the direction in which the second light travels is changed by about 180° at the curved portion 20b21. What is more, in this embodiment, the end portion 10a and the end portion 10b are respectively positioned at one end and the other end of the longitudinal direction (X direction) length of the laser device 10A.

Accordingly, a structure minimizing stray light coming to the end portion 10b is able to be obtained.

Furthermore, in this embodiment, the ring resonator filter 12A (mirror) is an example of the second reflecting unit.

The configuration achieving the above described effects is applicable to the laser device 10A including the ring resonator filter 12A serving as the second reflecting unit.

Furthermore, in this embodiment, the optical amplifier 14 is positioned between the first DBR unit 11 and the end portion 10a.

The configuration achieving the above described effects is applicable to the laser device 10A including the optical amplifier 14 between the first DBR unit 11 and the end portion 10a.

Furthermore, in this embodiment, the optical amplifier 14 is positioned between the divider 15 and the end portion 10a.

The configuration achieving the above described effects is applicable to the laser device 10A including the optical amplifier 14 between the divider 15 and the end portion 10a.

### First Modified Example

FIG. 2 is a plan view of a laser device 10B according to a first modified example. The laser device 10B according to the first modified example has the same configuration as the laser device 10A according to the embodiment, except that the positions of their optical amplifiers 14 and dividers 15 are in reverse. That is, in this first modified example, the optical amplifier 14 is positioned between the first DBR unit 11 and the divider 15.

This configuration also achieves the same effects as the above described embodiment.

### Second Modified Example

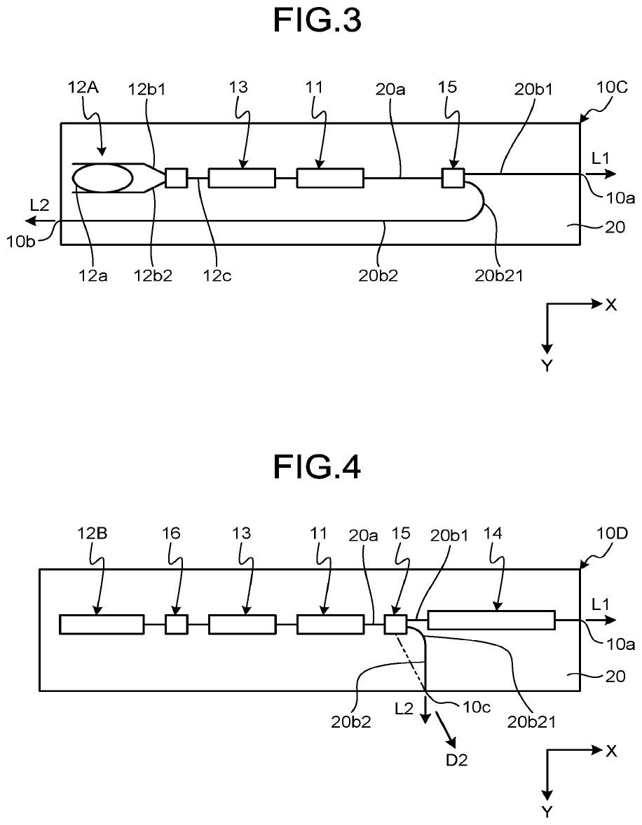

FIG. 3 is a plan view of a laser device 10C according to a second modified example. The laser device 10C according to the second modified example has the same configuration as the laser device 10A according to the embodiment, except that the laser device 10C does not include the optical amplifier 14.

This configuration also achieves the same effects as the above described embodiment.

### Third Modified Example

FIG. 4 is a plan view of a laser device 10D according to a third modified example. The laser device 10D according to the third modified example has the same configuration as the laser device 10A according to the embodiment, except that the laser device 10D: (1) includes, as the second reflecting unit, a second DBR unit 12B instead of the ring resonator filter 12A; (2) includes a phase adjusting unit 16; and (3) has an end portion 10c as the second end portion, the end portion 10c being at a position different from the position of the end portion 10b.

The second DBR unit 12B has, similarly to the first DBR unit 11, a waveguide (not illustrated in the drawings) including an SG-DBR configuration. The second DBR unit 12B is an example of the second reflecting unit and an example of the mirror.

The phase adjusting unit 16 is positioned between the first DBR unit 11 and the second DBR unit 12B. The phase adjusting unit 16 is positioned between the gain unit 13 and the second DBR unit 12B in this third modified example. However, the phase adjusting unit 16 may be positioned between the gain unit 13 and the first DBR unit 11.

The phase adjusting unit 16 has a passive waveguide (not illustrated in the drawings).

A microheater (not illustrated in the drawings) is provided in the phase adjusting unit 16 also. The microheater is a so-called resistance heating element and generates heat according to supply of electric current. A wiring structure, such as an electrode or a conductor layer, for supply of electric current is provided in the microheater.

Heating the phase adjusting unit 16 with the microheater changes the refractive index of the phase adjusting unit 16 and thereby enables adjustment of optical length of the laser resonator. Adjusting the optical length of the laser resonator enables frequencies of resonator modes (cavity modes) to be finely adjusted and shifted in the frequency axis direction. Fine adjustment of the resonator modes enables selection of resonator modes for laser oscillation and change of frequency in a small range. This phase adjusting unit 16 is also applicable to the above described embodiment, first modified example, and second modified example.

The end portion 10c is positioned at an end of a Y direction (transverse direction or width direction) width of the laser device 10D (semiconductor layered substrate 20). The direction in which the second light travels is changed by approximately 90° at the curved portion 20b21 of the waveguide 20b2. Furthermore, in this third modified example, the end portion 10c is positioned separately in a D2 direction (the second direction) from the divider 15, the D2 direction being different from the X-direction.

As described above, in this third modified example, the second DBR unit 12B (mirror or DBR mirror) is an example of the second reflecting unit.

This configuration also achieves the same effects as the above described embodiment. The third modified example also has an advantage that the device configuration is able to be made less complicated, for example.

In the configuration of FIG. 4, the ring resonator filter 12A may be provided instead of the second DBR unit 12B; or in any of the configurations of FIG. 1 to FIG. 3, the second DBR unit 12B may be provided instead of the ring resonator filter 12A.

The present disclosure enables obtainment of a laser device that facilitates detection of characteristics including wavelength of laser light, for example.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A laser device, comprising:
a first reflecting unit;
a second reflecting unit;
a gain unit provided between the first reflecting unit and the second reflecting unit;
a divider provided after the first reflecting unit and configured to divide laser light from the first reflecting unit into first light and second light;
a first end portion positioned separately from the divider in a first direction, and positioned after the divider, the first end portion being configured to output, as output light, the first light or the first light that has been amplified; and
a second end portion positioned separately from the divider in a second direction different from the first direction, the second end portion being configured to output the second light.

2. The laser device according to claim 1, further comprising a waveguide having a curved portion and configured to join the divider and the second end portion to each other.

3. The laser device according to claim 2, wherein a direction in which the second light travels is changed by approximately 180° at the curved portion.

4. The laser device according to claim 1, wherein
the first end portion and the second end position are respectively positioned at one end and another end of a longitudinal length of the laser device.

5. The laser device according to claim 1, wherein
the second reflecting unit is a ring resonator filter.

6. The laser device according to claim 1, wherein
the second reflecting unit is a mirror.

7. The laser device according to claim 6, wherein
the mirror is a DBR mirror.

8. The laser device according to claim 1, further comprising:
an optical amplifier provided between the first reflecting unit and the first end portion.

9. The laser device according to claim 8, wherein
the optical amplifier is positioned between the divider and the first end portion.

10. The laser device according to claim 8, wherein
the optical amplifier is positioned between the first reflecting unit and the divider.
